(19) United States
(12) Patent Application Publication
(10) Pub. No.: US 2015/0115388 A1
(43) Pub. Date: Apr. 30, 2015

(54) SOLID-STATE IMAGING DEVICE AND MANUFACTURING METHOD OF SOLID-STATE IMAGING DEVICE

(71) Applicant: KABUSHIKI KAISHA TOSHIBA, Tokyo (JP)

(72) Inventors: Kentaro EDA, Oita Oita (JP); Kenichi YOSHINO, Oita Oita (JP); Shintaro OKUJO, Oita Oita (JP); Hiroyuki FUKUMIZU, Yokohama Kanagawa (JP); Takaaki MINAMI, Oita Oita (JP); Takeshi YOUSYOU, Oita Oita (JP); Hiroaki ASHIDATE, Oita Oita (JP)

(21) Appl. No.: 14/523,721

(22) Filed: Oct. 24, 2014

(30) Foreign Application Priority Data
Oct. 29, 2013 (JP) 2013-224744

(51) Int. Cl. H01L 27/146

(52) U.S. Cl. CPC H01L 27/14645; H01L 27/1463; H01L 27/14627; H01L 27/14625; H01L 27/14621; H01L 27/14623; H01L 27/14685; H01L 27/14689
USPC 257/446; 438/70

(57) ABSTRACT

A solid-state imaging device includes a plurality of photoelectric transducers disposed in an array in a semiconductor layer. Each photoelectric transducer includes a first semiconductor region of a first conductivity type and a second semiconductor region of a second conductivity type. The first and second regions are in direct contact. An isolation region is between each adjacent pair of photoelectric transducers. The isolation region includes an insulating material extending from a surface of the semiconductor layer and a third semiconductor region of the first conductivity type surrounding the insulating material. The third semiconductor region is between the insulating material and the first semiconductor region, and the first semiconductor region is between the second and third semiconductor regions.

### CROSS-REFERENCE TO RELATED APPLICATION

This application is based upon and claims the benefit of priority from Japanese Patent Application No. 2013-224744, filed Oct. 29, 2013, the entire contents of which are incorporated herein by reference.

### FIELD

Embodiments described herein relate generally to a solid-state imaging device and a manufacturing method of the solid-state imaging device.

### BACKGROUND

In related art, an electronic device such as a digital camera or a mobile device with a camera function is provided with a camera module including a solid-state imaging device. The solid-state imaging device is provided with a plurality of photoelectric transducers which are two-dimensionally disposed in a matrix array so as to correspond to the respective pixels in a captured image. The respective photoelectric transducers in the matrix array perform photoelectric conversion of incident light into electric charge corresponding to an amount of received incident light and accumulates the electric charge as signal charge indicating luminance at the respective pixels.

In addition, an element isolation area for electric isolation between the photoelectric transducers is provided between the respective photoelectric transducers. The element isolation area is formed by forming a lattice-shaped trench (groove) surrounding the respective photoelectric transducers in a rectangular shape in a planar view in a semiconductor layer where the plurality of photoelectric transducers are formed and filling the inside of the trench with an insulating material or the like, for example.

The trench for element isolation is typically formed by reactive ion etching (RIE). However, the surface of the trench may be damaged by the RIE, such that crystal defects occur, and dangling bond occurs in some cases. Since electrons which are generated due to the dangling bond are generated regardless of presence of light which is incident on the photoelectric transducers, the electrons flow out as a so-called “dark current” from the photoelectric transducers, and appear as, for example, white scratches in a captured image, which results in degradation in image quality.

### DESCRIPTION OF THE DRAWINGS

FIG. 1 is a block diagram illustrating an outline configuration of a digital camera provided with a rear surface irradiation-type solid-state imaging device according to an embodiment.

FIG. 2 is a block diagram illustrating an outline configuration of the rear surface irradiation-type solid-state imaging device according to the embodiment.

FIG. 3 is an explanatory diagram illustrating a portion of an imaging sensor according to the embodiment in a cross-sectional view.

FIGS. 4A to 4D are cross-sectional views schematically illustrating a manufacturing procedure of the solid-state imaging device according to the embodiment.

FIGS. 5A to 5C are cross-sectional views schematically illustrating the manufacturing procedure of the solid-state imaging device according to the embodiment.

FIGS. 6A to 6C are cross-sectional views schematically illustrating the manufacturing procedure of the solid-state imaging device according to the embodiment.

FIG. 7 is a diagram illustrating a case where configurations of the photoelectric transducers and an element isolation area according to the embodiment are employed for a front surface irradiation-type image sensor.

### DETAILED DESCRIPTION

Embodiments provide a solid-state imaging device capable of reducing occurrence of a dark current and a manufacturing method of the solid-state imaging device.

In general, according to one embodiment, a solid-state imaging device includes a plurality of photoelectric transducers disposed in an array within a semiconductor layer. Each photoelectric transducer includes a first semiconductor region of a first conductivity type and a second semiconductor region of a second conductivity type. The first and second regions are in direct contact and form a photodiode. An isolation region is between each adjacent pair of photoelectric transducers. The isolation region includes an insulating material extending from a surface of the semiconductor layer into the semiconductor layer. In some embodiments, the isolation region is formed by etching a trench into the semiconductor layer and then ultimately filling the trench with insulating material. A third semiconductor region (also referred to as a “first conductivity-type semiconductor area”) of the first conductivity type surrounds the insulating material. In some embodiments, the third semiconductor region is formed by implanting ions into an outer peripheral surface of a trench etched in the semiconductor layer. In some other embodiments, the third semiconductor region can be formed by epitaxial growth on the outer peripheral surface of a trench etched in the semiconductor layer. The third semiconductor region is between the insulating material and the first semiconductor region, and the first semiconductor region is between the second and third semiconductor regions.

Hereinafter, a detailed description is given of a solid-state imaging device and a manufacturing method of the solid-state imaging device according to an embodiment with reference to accompanied drawings. In addition, the example embodiments are for purposes of explanation and are not the present disclosure is not limited to the example embodiments.

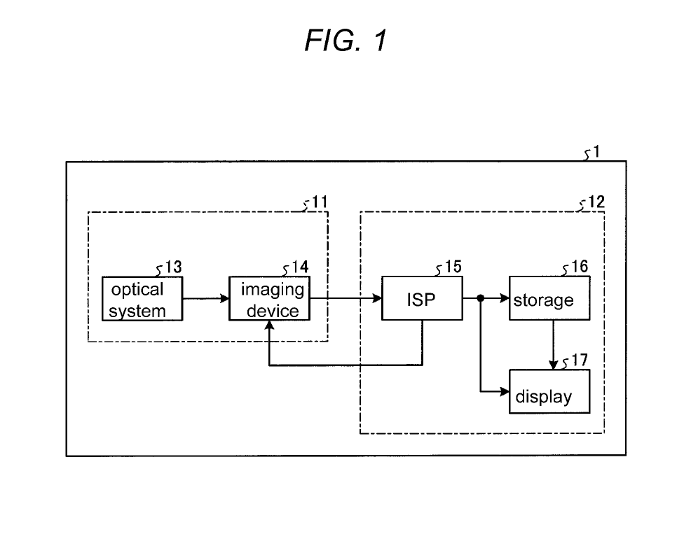

FIG. 1 is a block diagram which is an outline configuration diagram of a digital camera 1 provided with a solid-state imaging device 14 according to an embodiment. As illustrated in FIG. 1, the digital camera 1 includes a camera module 11 and a post-stage processing section 12.

The camera module 11 includes an imaging optical system 13 and the solid-state imaging device 14. The imaging optical system 13 receives light from an object and forms an image of the object. The solid-state imaging device 14 captures the image of the object which is formed by the imaging optical system 13 and generates an image signal for the post-stage processing section 12. The camera module 11 can be applied to or included in an electronic device such as a mobile terminal with a camera (e.g., a smart phone) as well as the digital camera 1.

The post-stage processing section 12 includes an image signal processor (ISP) 15, a storage unit 16, and a display unit 17. The ISP 15 performs signal processing on the image signal which is input from the solid-state imaging device 14. Such as the ISP 15 performs, for example, processing for higher image quality such as noise removal/reduction processing, defective pixel correction processing, and resolution conversion processing.

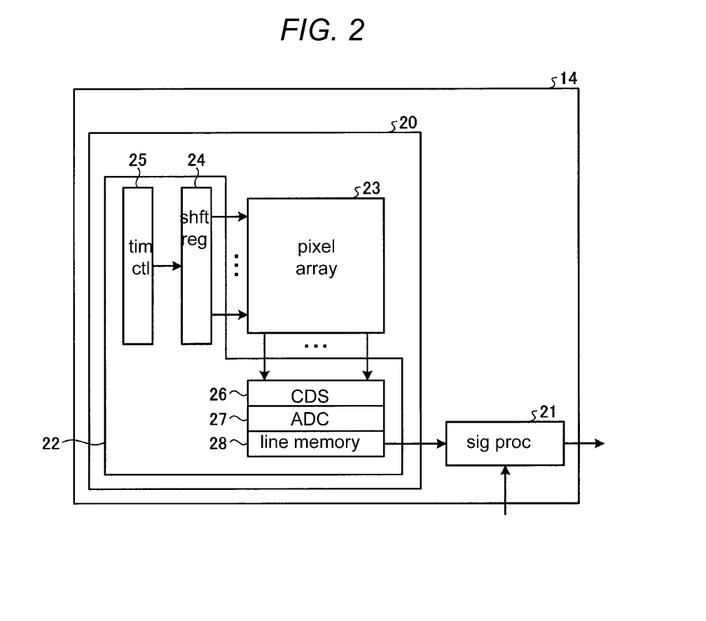

In addition, the ISP 15 generates an image signal after the signal processing to the storage unit 16, the display unit 17, and a signal processing circuit 21 included in the solid-state imaging device 14 in the camera module 11, which is described later (see FIG. 2). The image signal fed back from the ISP 15 to the camera module 11 is used for adjusting and controlling the solid-state imaging device 14.

The storage unit 16 stores as an image the image signal input from the ISP 15. In addition, the storage unit 16 outputs the image signal of the stored image to the display unit 17 in response to a user operation or the like. The display unit 17 displays the image corresponding to the image signal input from the ISP 15 or supplied from the storage unit 16. The display unit 17 is a liquid crystal display, for example.

Next, a description is given of the solid-state imaging device 14 included in the camera module 11 with reference to FIG. 2. FIG. 2 is a block diagram illustrating an outline configuration of the solid-state imaging device 14 according to the embodiment. As illustrated in FIG. 2, the solid-state imaging device 14 includes an image sensor 20 and the signal processing circuit 21.

Here, a description is given of a case where the image sensor 20 is a so-called rear surface irradiation-type complementary metal oxide semiconductor (CMOS) image sensor, in which a wiring layer is formed on a side opposite to a light incident surface—that is, the wiring layer is on the back-side of the device and light strikes the sensor from the front-side of the device side.

However, the image sensor 20 is not limited to the rear surface irradiation-type CMOS image sensor and may be an image sensor such as a front surface irradiation-type CMOS image sensor or a charge coupled device (CCD) image sensor.

The image sensor 20 includes a peripheral circuit 22 and a pixel array 23. In addition, the peripheral circuit 22 includes a vertical shift register 24, a timing control unit 25, a correlation double sampling (CDS) module 26, an analog-to-digital conversion (ADC) unit 27, and a line memory 28.

The pixel array 23 is provided in an imaging area of the image sensor 20. In the pixel array 23, the plurality of photoelectric transducers corresponding to the respective pixels in the captured image is arranged in a two-dimensional array shape (matrix shape) in the horizontal direction (row direction) and the vertical direction (column direction). In the pixel array 23, the respective photoelectric transducer corresponding to the respective pixels generate and accumulate signal electric charge (electrons, for example) corresponding to the amount of incident light.

The timing control unit 25 is a processing unit which outputs a pulse signal as a timing reference to the vertical shift register 24. The vertical shift register 24 is a processing unit which sends to the pixel array 23 a selection signal for sequentially selecting the photoelectric transducers to read the signal charge in row units from among the plurality of photoelectric transducers two-dimensionally disposed in the array (matrix) shape.

The pixel array 23 sends the signal charge accumulated by the respective photoelectric transducers, which are selected in units of row by the selection signal from the vertical shift register 24, to the CDS 26. The signal charge sent from the pixel array 23 is a pixel signal indicating luminance at each pixel.

The CDS 26 is a processing unit which removes noise from the pixel signal by the correlation double sampling and transmits the pixel signal to the ADC 27. The ADC 27 is a processing unit which converts the analog pixel signal input from the CDS 26 into a digital pixel signal and transmits the digital pixel signal to the line memory 28. The line memory 28 is a processing unit which temporarily holds the (digital) pixel signal input from the ADC 27 and outputs the pixel signals for each row of the photoelectric transducers in the pixel array 23 to the signal processing circuit 21.

The signal processing circuit 21 is a processing unit which performs predetermined signal processing on the pixel signal input from the line memory 28 and outputs the processed pixel signal to the post-stage processing section 12. The signal processing circuit 21 performs signal processing such as lens shading correction, scratch correction, and noise reduction.

As described above, the image sensor 20 captures an image by causing the plurality of photoelectric transducers arranged in the pixel array 23 to perform photoelectric conversion from the incident light to electric charge of an amount corresponding to the amount of the received light at the photoelectric transducers in the pixel array and to accumulate the electric charge. The peripheral circuit 22 reads the electric charge accumulated in the respective photoelectric transducers as a pixel signal.

According to the image sensor 20, an element isolation area is provided between the respective photoelectric transducers in the pixel array 23. In this embodiment, the element isolation area (isolation region) comprises a trench which is formed in a lattice shape by reactive ion etching (RIE) and an insulating member that fills the trench.

The surface of the trench is damaged by the RIE, causing crystal defects and dangling bonds in some cases. The photoelectric transducers which do not receive incident light may still accumulate electric charge (electrons) that is generated due to such dangling bond in some cases.

Such electric charge flows as a dark current from the pixel array 23 to the peripheral circuit 22 and appears as, for example, a white scratch in the captured image in some cases when the peripheral circuit 22 reads the pixel signal.

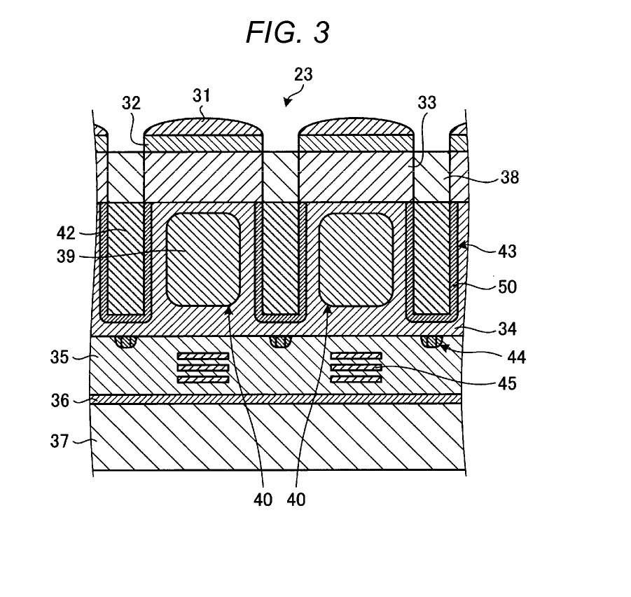

Thus, according to the solid-state imaging device 14, the pixel array 23 has a configuration for suppressing the dark current. Next, a description is given of a cross-sectional structure of the pixel array 23 capable of suppressing the dark current with reference to FIG. 3.

FIG. 3 is a diagram schematically illustrating a cross section of the pixel array 23 according to the embodiment. As illustrated in FIG. 3, the pixel array 23 includes a micro lens 31, a color filter 32, a waveguide 33, a first conductivity-type (e.g., P-type) semiconductor (e.g., Si: silicon in this example) layer 34, an insulation layer 35, an adhesive layer 36, and a support substrate 37 in order from the light incident side. The first conductivity-type semiconductor layer 34 may comprises a first semiconductor region of a first conductivity type.

The micro lens 31 is a planoconvex lens which collects incident light and directs it toward the respective photoelectric transducers. The color filter 32 is a filter which selectively allows light with any of red, green, blue, and white color to penetrate therethrough. The waveguide 33 is an area which guides the light penetrating through the color filter 32 to the side of the P-type Si layer 34 and is formed by silicon nitride, for example. In the periphery of the waveguide 33, a protective film 38 formed by silicon oxide, for example, is formed.

The P-type Si layer 34 is an area which can be formed by epitaxial growth of Si with P-type dopants such as boron (B). In addition, the P-type Si layer 34 may be formed by ion injection of P-type dopants into a Si wafer.

At a formation position of the photoelectric transducers 40 in the P-type Si layer 34, second conductivity-type (e.g., N-type) Si areas 39 are provided. The N-type Si areas 39 are formed by ion injection of N-type dopants such as phosphorus (P). In the pixel array 23, photodiodes formed by PN junction between the P-type Si layer 34 and the N-type Si areas 39 function as the photoelectric transducers 40.

Inside the insulation layer 35, a reading gate 44, which reads the signal electric charge from the photoelectric transducer 40, and a multilayer wiring 45 are provided. Other elements may be present in the insulating layer 35 as well. The adhesive layer 36 and the support substrate 37 are described later.

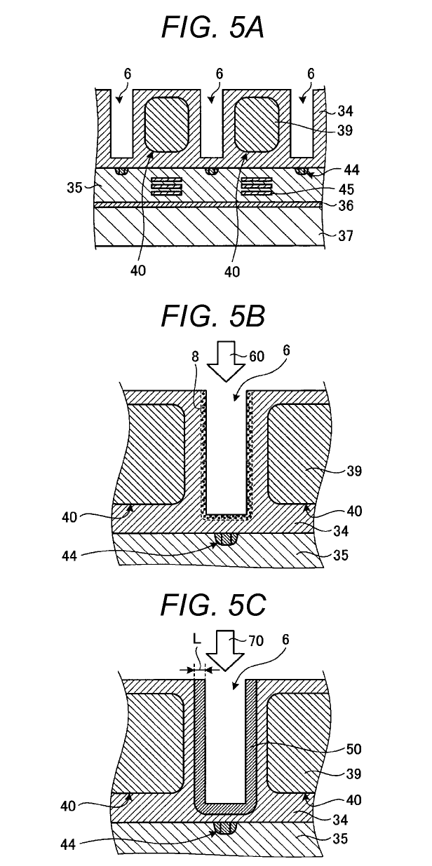

In addition, an element isolation area 43 is provided between the respective photoelectric transducers 40. The element isolation area 43 is provided so as to divide the P-type Si layer 34 for each photoelectric transducer 40. A trench 6 (see FIGS. 5A to 5C), which forms a lattice shape in a planar view (e.g., top-down device view) is provided in the element isolation area 43.

A first conductivity-type (P-type) Si area 50 (third semiconductor region) including activated dopants is formed on the outer peripheral surface of the trench 6, so as to cover the outer peripheral surface of the trench 6. Here, a state where the P-type dopants (boron) are activated in the embodiment represents a state where boron is thermally diffused in the P-type Si area 50.

The inside of the trench 6, on whose outer peripheral surface the P-type Si area 50 is formed, is filled with an insulating member 42 made of silicon oxide or the like.

In addition, the first conductivity-type (P-type) Si area 50 has higher concentration of P-type dopants than that in the P-type Si layer 34. Specifically, the concentration of boron in the P-type Si layer 34 is from 1.0×10¹⁴ cm⁻³ to 1.0×10¹⁶ cm⁻³ while the concentration of boron in the P-type Si area 50 is from 1.0×10¹⁷ cm⁻³ to 1.0×10¹⁹ cm⁻³.

It is possible to generate multiple dopants activated by the laser annealing processing, which is described later, by increasing the concentration of dopants included in the P-type Si area 50 as described above. By such a configuration, the P-type Si area 50 may effectively capture electrons, which are generated due to dangling bonds, at the outer peripheral surface of the trench 6.

In addition, it is possible to simplify the manufacturing process and to shorten the manufacturing procedure by introducing the same conductivity-type dopants as those included in the P-type Si layer 34 into the P-type Si area 50.

Since the pixel array 23 includes the P-type Si area 50, which includes activated boron, so as to cover the outer peripheral surface of the trench 6 as described above, activated boron may effectively capture the electrons, which are generated due to dangling bonds, at the outer peripheral surface of the trench 6. For this reason, there is little chance that the electrons which are generated due to dangling bonds flow from the trench 6 into the N-type Si areas 39 as a charge accumulated area in the photodiode 40, and therefore, it is possible to reduce occurrence of the dark current.

Therefore, according to the pixel array 23, the amount of the dark current flowing from the pixel array 23 to the peripheral circuit 22 is significantly reduced when the peripheral circuit 22 reads the pixel signal, and it is possible to reduce occurrence of the problem of a white scratch appearing in the captured image.

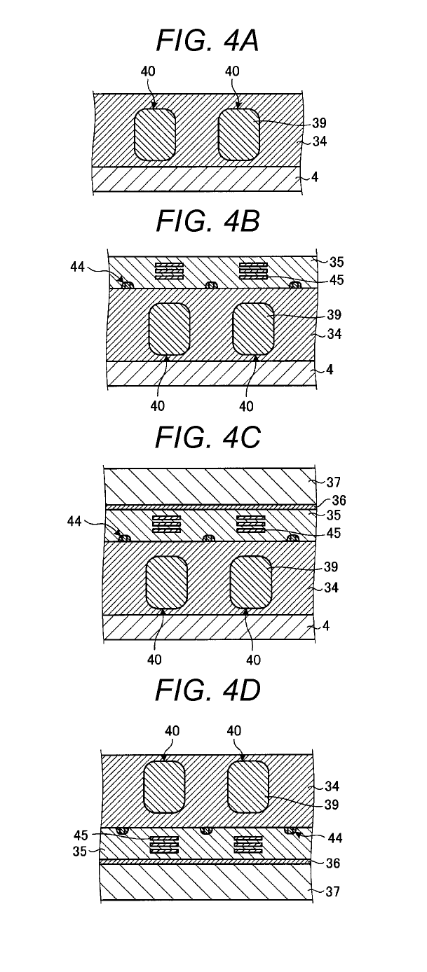

Next, a description is given of a manufacturing method of the solid-state imaging device 14 including a forming method of such a pixel array 23 with reference to FIGS. 4A to 6C. In addition, the manufacturing method corresponding to a portion other than the pixel array 23 in the solid-state imaging device 14 is the same as that of a typical CMOS image sensor. Therefore, a description is given of the manufacturing method of the pixel array 23 in the solid-state imaging device 14 below.

FIGS. 4A to 6C are cross-sectional views schematically illustrating a manufacturing procedure of the solid-state imaging device 14 according to the embodiment. FIGS. 4A to 6C selectively illustrate the manufacturing procedure of the portion, which is illustrated in FIG. 3, in the pixel array 23.

As illustrated in FIG. 4A, the P-type Si layer 34 is formed on the semiconductor substrate 4, such as a Si wafer, for manufacturing the pixel array 23. At this time, the P-type Si layer 34 is formed by epitaxial growth of a Si layer including P-type dopants such as boron on the semiconductor substrate 4, for example. In addition, the P-type Si layer 34 may be formed by performing ion injection of P-type dopants into the Si wafer and performing annealing processing.

Subsequently, the N-type Si areas 39 are two-dimensionally disposed in the matrix shape in the P-type Si layer 34 by performing ion injection of the N-type dopants such as phosphorus at the formation positions of the photoelectric transducers 40 in the P-type Si layer 34 and performing the annealing processing. Owing to such a configuration, the photoelectric transducers 40, which are photodiodes, are formed by the PN junction between the P-type Si layer 34 and the N-type Si areas 39 in the pixel array 23.

Thereafter, the insulation layer 35 is formed along with the reading gate 44, the multilayer wiring 45, and the like on the P-type Si layer 34 as illustrated in FIG. 4B. In such a process, a procedure of forming the silicon oxide layer, a procedure of forming the predetermined wiring pattern on the silicon oxide layer, and a procedure of forming the multilayer wiring 45 by filling the wiring pattern with Cu or the like are repeated after forming the reading gate 44 and the like on the upper surface of the P-type Si layer 34. Owing to such a configuration, the insulation layer 35 with the reading gate 44, the multilayer wiring 45, and the like provided therein is formed.

Next, the adhesive layer 36 is provided by applying an adhesive agent to the upper surface of the insulation layer 35, and the support substrate 37, such as a Si wafer, is attached to the upper surface of the adhesive layer 36 as illustrated in FIG. 4C. Thereafter, the structure illustrated in FIG. 4D is rotated upside down, the semiconductor substrate 4 is then polished from the rear surface thereof (from the upper surface side in this example) by a polishing apparatus such as a grinder, and the semiconductor substrate 4 is thinned to a predetermined thickness.

Then, the rear surface side of the semiconductor substrate 4 is further polished by chemical mechanical polishing (CMP), for example, and the rear surface (the upper surface in this example) as a light receiving surface of the P-type Si layer 34 is exposed as illustrated in FIG. 4D.

Thereafter, the trench 6 for the element isolation is formed by RIE, for example at the formation position of the element isolation area 43 (see FIG. 3) in the P-type Si layer 34, namely in the P-type Si layer 34 between the respective N-type Si areas 39, as illustrated in FIG. 5A.

After the trench is formed, the P-type dopants 8 such as boron (B: boron in this example) are injected from the inner peripheral surface of the trench 6 to the inside of the P-type Si layer 34 by using an ion injecting apparatus, for example, as illustrated in FIG. 5B. As processing conditions for the ion injection of boron 8, an acceleration voltage is set to 5 keV, and a dose amount is set to 1E15/cm², for example. Specifically, irradiation of the inner peripheral surface of the trench 6 with an ion beam 60 is performed separately for the inner surface and the bottom surface of the trench 6 multiple times.

In relation to the irradiation method of the inner peripheral surface of the trench 6 with the ion beam 60, the inner surface of the trench 6 is irradiated with the ion beam 60 in an oblique direction from an opening surface of the trench 6 to the inner surface of the trench 6. The oblique direction described herein is a direction which inclines in an angle with respect to a normal direction of the support substrate 37, for example. In addition, the bottom surface of the trench 6 is irradiated with the ion beam 60 in a vertically downward direction from the opening of the trench 6 to the bottom surface of the trench 6.

By performing the irradiation with the ion beam 60 separately on the plurality of irradiation areas as described above, it is possible to uniformly inject the boron 8 into the outer peripheral surface of the trench 6.

Although the boron 8 is injected to the outer peripheral surface of the trench 6 as illustrated in FIG. 5B in this embodiment, the boron 8 may be injected to a position which is located in a direction toward the inside of the P-type Si layer 34 from the outer peripheral surface of the trench 6. In such a case, the injected boron 8 is thermally diffused in a width direction of the P-type Si layer 34 by the laser annealing processing, and the P-type Si area 50, which covers the outer peripheral surface of the trench 6, is formed.

By injecting the boron 8 at a position which is located in a direction toward the inside of the P-type Si layer 34 from the outer peripheral surface of the trench 6 as described above, a direction toward the outer peripheral surface of the trench 6 is added to the directions in which the boron 8 is diffused. For this reason, it is possible to reduce the distance by which the boron 8 is diffused as compared with the case where the boron 8 is injected to the outer peripheral surface of the trench 6 and is diffused in a direction toward the inside of the P-type Si layer 34. Accordingly, it is possible to shorten the annealing time for forming the P-type Si area 50.

Next, the laser annealing processing is performed on the inner peripheral surface of the trench 6 after the injection of the boron 8, by using a laser annealing apparatus, as illustrated in FIG. 5C. As conditions for the laser annealing processing, a wavelength of the laser beam is set from 200 nm to 1,000 nm, laser power is set from 0.3 J/cm³ to 3 J/cm³, and a pulse width is set from 15 ns to 300 ns, for example. Specifically, the inner peripheral surface of the trench 6 is irradiated with a laser beam 70 separately for the inner surface (sidewall) and the bottom surface of the trench 6 a plurality of times.

In relation to the irradiation method of the inner peripheral surface of the trench 6 with the laser beam 70, the inner surface of the trench 6 is irradiated with the laser beam 70 in an oblique direction from the opening of the trench 6 to the inner surface (sidewall) of the trench 6. The oblique direction described herein is a direction which inclines in a predetermined angle with respect to the normal direction of the support substrate 37, for example. In addition, the bottom surface of the trench 6 is irradiated with the laser beam 70 in a vertically downward direction from the opening of the trench 6 to the bottom surface of the trench 6.

By performing the irradiation with the laser beam 70 separately on the plurality of irradiation areas (e.g., sidewalls and bottom surface) as described above, it is possible to uniformly activate the boron 8 injected to the outer peripheral surface of the trench 6 and to acquire a uniform thickness of the P-type Si area 50 which covers the outer peripheral surface of the trench 6.

In the laser annealing processing, it is possible to control diffusion of the boron 8 injected to the outer peripheral surface of the trench 6. Furthermore, since a laser pulse is incident from the opening of the trench 6 for only a short time, it is possible to heat the peripheral surface of the trench 6 while maintaining the insulation layer 35 (and the reading gate 44 and the multilayer wiring 45 provided therein) at a relatively low temperature. That is, according to the embodiment, it is possible to perform the annealing processing without adversely affecting the reading gate 44 and the multilayer wiring 45 by heating.

With the boron 8 irradiated with the laser beam 70 and consequently thermally diffused in a direction toward the outer surface of the trench 6 in the P-type Si layer 34, the P-type Si area 50 is formed as illustrated in FIG. 5C. The P-type Si area 50 is formed such that a distance L from the outer peripheral surface of the trench 6 to an interface of the P-type Si layer 34 is within a range from 50 nm to 400 nm. That is, according to the embodiment, the conditions for the laser annealing processing are set such that the diffusion of the boron 8 is within the distance L.

By forming the P-type Si area 50 including the activated boron 8 so as not to be in contact with the side surface of the N-type Si area 39 as described above, a decrease in the light receiving area in the N-type Si area 39 is suppressed.

In addition, the P-type Si area 50 may be formed so as to cover the outer peripheral surface of the trench 6 while being slightly separate from the outer peripheral surface of the trench 6. That is, the P-type Si layer 34 is present between the outer peripheral surface of the trench 6 and an interface of the P-type Si area 50, and the electrons generated due to the dangling bond may be trapped in the P-type Si layer 34 and thus blocked from the P-type Si area 50. Since there is little chance that the electrons generated due to dangling bonds flow from the trench 6 into the N-type Si area 39 even in such a configuration, it is possible to reduce occurrence of dark current.

In addition, the P-type Si area 50 is not limited to a case of being formed so as to surround the entire outer peripheral surface of the trench 6 as illustrated in FIG. 5C, and a plurality of independent P-type Si areas may be formed, and the outer peripheral surface of the trench 6 may be surrounded by the plurality of P-type Si areas. It is also possible to reduce occurrence of the dark current in the same manner even in such a configuration.

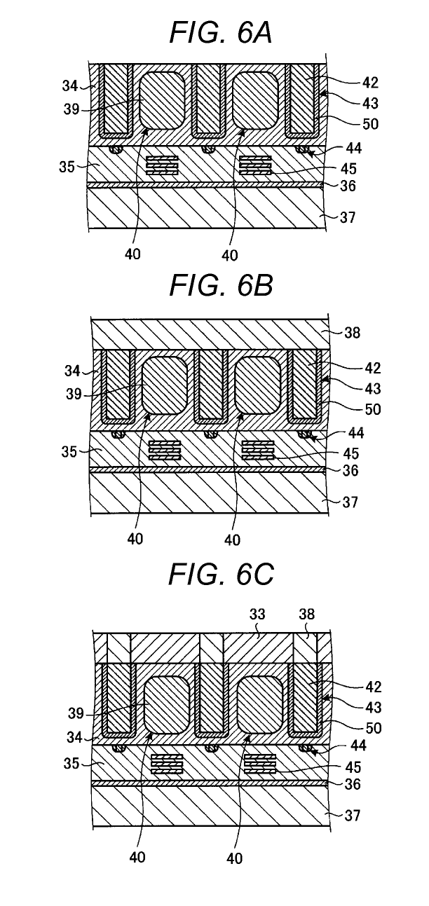

Next, the inside of the trench 6, the outer peripheral surface covered with the P-type Si area 50, is filled with the insulating member 42 such as silicon oxide by using chemical vapor deposition (CVD), for example, and the element isolation area 43 is formed as illustrated in FIG. 6A. Owing to such a configuration, electrical isolation is established between the photoelectric transducers 40.

In addition, the inside of the trench 6, the inner peripheral surface of which is covered with an insulating film such as silicon oxide, may be filled with a light blocking member such as aluminum by using the CVD, for example, after the insulating film is formed by using CVD, sputtering, or the like on the inner peripheral surface of the trench 6, the outer peripheral surface of which is covered with the P-type Si area 50. Owing to such a configuration, element electric and optical isolation is established between the photoelectric transducers 40.

Next, the protective film 38 is formed on the upper surface of the P-type Si layer 34 by laminating silicon oxide by using the CVD, for example, as illustrated in FIG. 6B, and the protective film 38 on the photoelectric transducers 40 is selectively removed as illustrated in FIG. 6C.

Then, the waveguide 33 is formed by laminating silicon nitride on the inside of an opening, which is obtained by selectively removing the protective film 38, by using the CVD, for example, as illustrated in FIG. 6C. Thereafter, the pixel array 23 illustrated in FIG. 3 is formed by sequentially forming the color filter 32 and the micro lens 31 on the upper surface of the waveguide 33.

According to the embodiment, the P-type Si area 50 including the boron 8, which is activated, covers the outer peripheral surface of the trench 6 and is formed by doping the boron 8 in the outer peripheral surface of the trench 6 and then diffusing the boron 8 by the laser annealing processing.

By such formation, the activated boron in the P-type Si area 50 may effectively capture the electrons which are generated due to dangling bonds in the outer peripheral surface of the trench 6. For this reason, there is little concern that the electrons generated due to dangling bonds flow from the trench 6 to the N-type Si area 39, and therefore, it is possible to reduce occurrence of dark current.

Therefore, according to the solid-state imaging device 14 manufactured in the embodiment, the flowing of little to no dark current from the pixel array 23 to the peripheral circuit 22 occurs when the peripheral circuit 22 reads the pixel signal, and therefore, it is possible to reduce occurrence of a white scratch occurring in the captured image.

Although the boron 8 is doped in the outer peripheral surface of the trench 6 by using the ion injecting apparatus in the aforementioned embodiment, the boron 8 may be doped in the outer peripheral surface of the trench 6 by using a plasma doping apparatus.

In addition, the above description is given of the case where the image sensor 20 according to the embodiment is a rear surface irradiation-type image sensor, the aforementioned configurations of the photoelectric transducers 40 and the element isolation area 43 may be employed for a front surface irradiation-type image sensor.

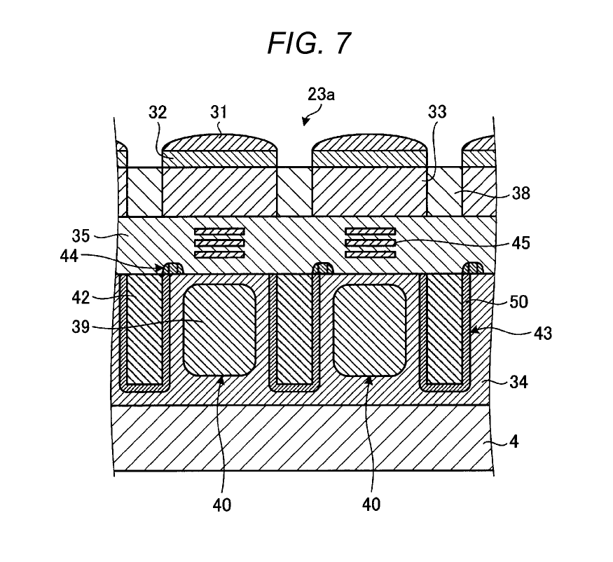

FIG. 7 is an explanatory diagram illustrating a case where the configurations of the photoelectric transducers 40 and the element isolation area 43 according to an embodiment are employed for a front surface irradiation-type image sensor. FIG. 7 illustrates a portion of a cross section schematically illustrating a pixel array 23a in a front surface irradiation-type image sensor. In addition, the same reference numerals as those in FIG. 3 are given to components with the same functions as those of the components illustrated in FIG. 3 from among the components illustrated in FIG. 7, and the descriptions thereof will be omitted.

As illustrated in FIG. 7, the pixel array 23a has the same configuration as that of the pixel array 23 illustrated in FIG. 3 other than that the P-type Si layer 34 is provided on the semiconductor substrate 4 and in that the insulation layer 35 with the reading gate 44 and the multilayer wiring 45 provided therein is arranged on a side of a light receiving surface (upper surface) of the P-type Si layer 34.

Even if the configurations of the photoelectric transducers 40 and the element isolation area 43 according to the embodiment are employed for the front surface irradiation type image sensor, the formation methods and the configurations of the photoelectric transducers 40 and the element isolation area 43 are the same as those for the pixel array 23 illustrated in FIG. 3.

Accordingly, since the pixel array 23a illustrated in FIG. 7 also includes the P-type Si area 50 including the activated boron 8, the amount of the dark current flowing from the pixel array 23 to the peripheral circuit 22 significantly decreases when the peripheral circuit 22 reads the pixel signal, and it is possible to reduce occurrence of a white scratch appearing in the captured image.

Although in the described example embodiments the first conductive type corresponds to the P type and the second conductive type corresponds to the N type, the first conductive type may be the N type, the second conductive type may be the P type, and an N-type Si area may be formed so as to cover or surround the outer peripheral surface of the trench.

In such a case, the N-type Si layer is formed by causing epitaxial growth of Si with doped N-type dopants such as phosphorus (P). In addition, the N-type Si area including the activated N-type dopants is formed by doping the N-type dopants, for example, phosphorus (P) in the outer peripheral surface of the trench and then diffusing phosphorus by the laser annealing processing.

Activated phosphorus in the N-type Si area effectively captures the electric charge generated in the outer peripheral surface of the trench due to the dangling bond, and it is possible to reduce occurrence of the dark current by doping phosphorus in the outer peripheral surface of the trench, then diffusing phosphorus by the laser annealing processing, and forming the N-type Si area including activated phosphorus so as to cover the outer peripheral surface of the trench.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device, comprising:
a plurality of photoelectric transducers in an array within a semiconductor layer, each photoelectric transducer including a first semiconductor region of a first conductivity type and a second semiconductor region of a second conductivity type, the first and second semiconductor regions being in direct contact with each other; and
an isolation region between each adjacent pair of photoelectric transducers in the plurality of photoelectric transducers, the isolation region comprising an insulating material extending from a surface of the semiconductor layer into the semiconductor layer and a third semiconductor region of the first conductivity type surrounding the insulating material, wherein
the third semiconductor region is between the insulating material and the first semiconductor region, and
the first semiconductor region is between the second and third semiconductor regions.

2. The device according to claim 1, wherein a concentration of activated dopants of the first conductivity type in the third semiconductor region is greater than a concentration of activated dopants of the first conductivity type in the first semiconductor region

3. The device according to claim 2, wherein the concentration of activated dopants of the first conductivity type in the first semiconductor region is from 1.0×10¹⁴ cm⁻³ to 1.0×10¹⁶ cm⁻³ and the concentration of activated dopants of the first conductivity type in the third semiconductor region is from 1.0×10¹⁷ cm⁻³ to 1.0×10¹⁹ cm⁻³.

4. A solid-state imaging device comprising:
a plurality of photoelectric transducers arranged in a matrix shape over a surface, wherein each transducer includes a second conductivity-type area disposed in a first conductivity-type layer to form a photo-diode; and
a plurality of element isolation areas disposed between adjacent photoelectric transducers, wherein each element isolation area includes a trench formed in the first conductivity-type layer, a first conductivity-type area covering an outer peripheral surface of the trench, the first conductivity-type area having activated dopants, and an insulating member that fills the trench.

5. The device according to claim 4, wherein the first conductivity-type layer is p-type and the second conductive type area is a n-type, and
the activated dopants are p-type dopants.

6. The device according to claim 4, wherein the first conductivity-type area has a thickness of between 50 nanometers to 400 nanometers.

7. The device according to claim 4, wherein a thickness of the first conductivity-type area on the outer peripheral surface of the trench is uniform.

8. A method for manufacturing a solid-state imaging device, the method comprising:
forming a plurality of photoelectric transducers in array within a semiconductor layer, each photoelectric transducer including a first semiconductor region of first conductivity type and a second semiconductor region, the first and second regions being in direct contact with each other; of a second conductivity type semiconductor area in a matrix shape on a first conductivity-type semiconductor layer, each adjacent pair of photoelectric transducers having an isolation region formed therebetween, the isolation region comprising an insulating material extending from a surface of the semiconductor layer into the semiconductor layer and a third semiconductor region of the first conductivity type surrounding the insulating material, such that the third semiconductor region is between the insulating material and the first semiconductor region, and the first semiconductor region is between the second and third semiconductor regions, wherein
forming the isolation region includes:
forming a trench in the semiconductor layer between each adjacent pair of photoelectric transducers,
forming the third semiconductor region on an outer peripheral surface of the trench, and
filling the trench with the insulating material.

9. The method according to claim 8, wherein forming the third semiconductor region includes:
implanting dopants of the first conductivity type in the outer peripheral surface of the trench, and
activating the dopants by a laser annealing processing.

10. The method according to claim 9, wherein the implanting of dopants in the outer peripheral surface of the trench is performed by ion injection.

11. The method according to claim 10, wherein the ion injection occurs at a first angle that is orthogonal to the surface of the semiconductor layer and a second angle that oblique to the surface of the semiconductor layer.

12. The method according to claim 8, wherein the third semiconductor region is formed on the outer peripheral surface of the trench by a plasma doping ion injection method including dopants of the first conductivity type.

13. The method according to claim 12, wherein forming the third semiconductor region on the outer peripheral surface of the trench further includes activating the dopants by a laser annealing process.

14. The method according to claim 8, wherein the trench is formed by reactive ion etching (RIE) of the first semiconductor region.

15. The method according to claim 8, wherein forming the third semiconductor region on the outer peripheral surface of the trench includes injecting a p-type dopant through the outer peripheral surface of the trench into first semiconductor region and thermally diffusing the p-type dopant into the first semiconductor region by a laser annealing process.

16. The method according to claim 15, wherein the laser annealing is performed by irradiating the outer peripheral surface of the trench with a laser beam a plurality of times to create a uniform thickness for the third semiconductor region.

17. The method according to claim 16, wherein the third semiconductor region is formed on the outer peripheral surface of the trench such that a distance from the outer peripheral surface of the trench to an interface between the first semiconductor region and the third semiconductor region is in a range of about 50 nm to about 400 nm.

18. The method according to claim 8, wherein the filling of the trench with insulating material includes depositing the insulating material using chemical vapor deposition.

19. The method according to claim 18, wherein the insulating member includes a light blocking member.

20. The method according to claim 8, further comprising forming a waveguide, color filter, and microlens on each photoelectric transducer.
